(19) United States
(12) Patent Application Publication
(10) Pub. No.: US 2011/0290307 A1
(43) Pub. Date: Dec. 1, 2011

(54) MODULAR SOLAR PANEL SYSTEM

(75) Inventors: Robert Emmett Workman, Morgan, UT (US); Norm Krantz, Logan, UT (US)

(73) Assignee: Goal Zero LLC

(21) Appl. No.: 13/111,442

(22) Filed: May 19, 2011

Related U.S. Application Data
(60) Provisional application No. 61/350,364, filed on Jun. 1, 2010.

(51) Int. Cl. H01L 31/048; H01M 10/46

(52) U.S. Cl. 136/251; 320/101

(57) ABSTRACT

A modular solar panel system includes solar panels mechanically and electrically interconnectable to create a modular solar panel array, and an electrical connection module on each panel, the module having an input connection and an output connection for electrically interconnecting the panels in the solar panel array. A peripheral frame member is disposed about each panel, and includes a first set of receptacles arranged on a back face, and a second set of receptacles arranged along an outside edge. The second set of receptacles are arranged along each side so that the receptacles on one panel align with the receptacles on another panel when placed adjacent one another in a generally planar edge-to-edge manner. A support structure supports the solar panel array, and includes a third set of receptacles that have a size, shape and spacing that correspond to the size, shape and spacing of the first set of receptacles on the back face and are alignable with one another to facilitate mounting of the solar panels to the support structure. Connection devices are configured to interconnect the solar panels to one another and to the support structure.

### CROSS REFERENCE TO RELATED APPLICATIONS

The present Application claims the benefit of priority under 35 U.S.C. §119(e)(1) of U.S. Provisional Patent Application No. 61/350,364, titled “Modular Solar Panel System” and filed on Jun. 1, 2010, the disclosure of which is incorporated herein by reference in its entirety.

### FIELD

The present invention relates to a modular solar panel system. The invention more particularly relates to a system for interconnecting photovoltaic (PV) solar panels to one another and for mounting the connected solar panels to a support structure using quick-connect connection devices, so that a modular solar panel assembly can be quickly and conveniently assembled to provide a portable source of power, and can be easily disassembled to facilitate transport of the system to other locations.

### BACKGROUND

This section is intended to provide a background or context to the invention recited in the claims. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

PV solar panels or cells are generally known and are typically mounted in a permanent manner to receive sunlight for the generation of electricity. Such mountings may be fixed, or may be movable (e.g. to track movement of the sun, etc.), and are typically configured to mechanically connect the solar panels individually to support members in a fixed quantity intended to provide the desired electric power generation requirements. However, such known systems tend to have certain disadvantages. For example, such known systems are typically intended to be fixed in place in a relatively permanent manner and are not easily or readily reconfigurable or transportable to provide a modular and mobile source of power that is independent of an electric grid.

Accordingly, It would be desirable to provide an improved modular solar panel system that overcomes the disadvantages of the known solar panel systems.

It would be desirable to provide an improved modular solar panel system that permits mechanical interconnection of multiple solar panels to one another to form a modular solar panel array having any number of solar panels intended to suit the electric power needs of a particular application.

It would also be desirable to provide an improved modular solar panel system having individual solar panels each having a electrical connection module (e.g. junction box, etc.) that permits quick and convenient electrical interconnection of any number of solar panels in the solar panel array (e.g. in a building-block manner or the like).

It would also be desirable to provide an improved modular solar panel system having quick-connect connector devices that are configured to rapidly and easily connect the solar panels to one another.

It would also be desirable to provide an improved modular solar panel system having a connection system with quick-connect connector devices that are configured to rapidly and easily connect the solar panel array to a support structure, such as a space frame, simple frames, stands, racks, vehicle rack (e.g. roof rack), or other suitable structure that may be generally fixed and permanent; or maybe mobile, and/or configured for rapid assembly and disassembly.

It would also be desirable to provide an improved modular solar panel system having a connection system with receptacles in the solar panels that are configured to permit mounting of the solar panels to the support structure in any of a variety of orientations (e.g. right side up, upside down, side ways, etc.).

It would be desirable to provide an improved modular solar panel system that includes any one or more of these advantageous features.

### SUMMARY

According to one embodiment, a modular solar panel system is provided that includes a plurality of solar panels that are mechanically and electrically interconnectable to create a modular solar panel array (e.g. in a building-block manner or the like) having any desired number of solar panels intended to suit the electric power requirements of a particular application and any of a wide variety of loads (i.e. electrical devices, lighting, appliances, tools, portable medical equipment, communication devices, etc.). Each panel includes an electrical connection module having an input connection and an output connection for electrically interconnecting the panels in the solar panel array. The electrical connection modules permits chaining the panels together (e.g. a ‘plug-and-play’ manner or the like) that permits only one-way, correct-orientation connection of the panels to one another, and have no exposed electrically conductive surfaces.

Each panel also includes a peripheral frame member, The peripheral frame member includes a first set of receptacles arranged on a back face of the solar panel, and a second set of receptacles arranged along an outside edge of the solar panel. The second set of receptacles are arranged along each side of the panel so that the receptacles on one panel align with the receptacles on another panel when placed adjacent one another in a generally planar edge-to-edge manner, to facilitate mechanically connecting the panels using a connection device configured to engage the aligned second set of receptacles on the adjacent solar panels.

A support structure is provided for receiving (e.g. supporting, securing, etc.) the solar panel array, or for otherwise mounting the solar panel array thereto. The support structure may be a modular structure (e.g. a space frame or the like) configured to be quickly constructed or assembled in a size intended to adapt to the size and support requirements of the solar panel array. The support structure may also be a stand, rack or other type of frame member that is fixed, or collapsible, and is readily transportable from one location where an off-grid source of electric power is desired to another location. The support structure may also be a rack or other framework on a vehicle (e.g. car, truck, bus, recreational vehicle (RV), etc.). The support structure includes a third set of receptacles that have a size, shape and spacing that corresponds substantially to the size, shape and spacing of the first set of receptacles on the back face of the panel frame member and are alignable with one another to facilitate mounting of the solar panels to the support structure using a connection device configured to engage the aligned receptacles on the support structure and solar panels. Alternatively, the support structure may include projections sized, shaped, and spaced to align with the first set of receptacles on the back face of the solar panel frame so that they releasably engage one another in a secure manner (e.g. slide-lock, etc.).

Quick-release connection devices are provided for interconnecting the solar panels to one another and to the support structure. According to one embodiment, the connection devices are twist-lock connectors with two lateral stationary posts and a rotatable (e.g. quarter-turn) center “T” post that is pivotally coupled to a locking lever having an over-center cam. The twist-lock connectors are configured to releasably engage the aligned sets of receptacles on (i) adjacent outside edges of the solar panel frame members for connecting the panels into a solar panel array, and (ii) the back face of the solar panel frame members and the support structure to mount the solar panel array on the support structure.

One or more battery modules may be electrically coupled to the electrical connection modules of the solar panels to store electrical energy generated by the solar panels. is (among others) modular, portable, stackable, electrically chainable, reconfigurable, and rechargeable. An inverter module may be provided that is connectible to the battery module and includes a ‘multi-standard’ socket configured to receive any of a wide variety of electric plug configurations to provide a source of AC electric power. One example of a battery module and inverter module are shown in U.S. Patent Application No. 61/308,712 titled “Modular and Portable Battery Pack Power System” filed on Feb. 26, 2010, the disclosure of which is hereby incorporated by reference in its entirety. Another example of a battery module and inverter module are shown in U.S. Patent Application No. 61/349,735 titled “Modular and Portable Battery Pack Power System” filed on May 28, 2010, the disclosure of which is hereby incorporated by reference in its entirety.

### BRIEF DESCRIPTION OF THE DRAWINGS

The disclosure will become more fully understood from the following detailed description, taken in conjunction with the accompanying figures, wherein like reference numerals refer to like elements, in which:

FIG. 1 is a back perspective view of a modular solar panel system having adjacent solar panels with peripheral frame members and electrical connection modules, and twist-lock connectors for assembling individual panels into a solar panel array according to an exemplary embodiment.

FIG. 2 is a back perspective view of a modular solar panel system having adjacent solar panels with peripheral frame members and electrical connection modules, and twist-lock connectors for assembling individual panels into a solar panel array, and for connecting the solar panel array to a support structure, according to an exemplary embodiment.

FIG. 3 is a back perspective view of a modular solar panel system having adjacent solar panels with peripheral frame members and electrical connection modules, and twist-lock connectors for assembling individual panels into a solar panel array, and for connecting the solar panel array to a support structure, with the connectors in various stages of activation (or deployment), according to an exemplary embodiment.

FIG. 4 is a back view of a modular solar panel system having adjacent solar panels with peripheral frame members and electrical connection modules, and twist-lock connectors for assembling individual panels into a solar panel array, and for connecting the solar panel array to a support structure, according to an exemplary embodiment.

FIG. 5 is a back view of a modular solar panel system having adjacent solar panels with peripheral frame members and electrical connection modules, and twist-lock connectors for assembling individual panels into a solar panel array, and for connecting the solar panel array to a support structure, with the connectors in various stages of activation (or deployment), according to an exemplary embodiment.

FIG. 6 is a front view of a modular solar panel system according to an exemplary embodiment.

FIG. 7 is a side view of a modular solar panel system having solar panels with peripheral frame members and twist-lock connectors for connecting the solar panel array to a support structure, with the connectors in various stages of activation (or deployment), according to an exemplary embodiment.

FIG. 8 is another side view of a modular solar panel system having solar panels with peripheral frame members and twist-lock connectors for connecting the solar panel array to a support structure, with the connectors in various stages of activation (or deployment), according to an exemplary embodiment.

FIG. 9 is an end view of a modular solar panel system having adjacent solar panels connected into a solar panel array and with peripheral frame members and twist-lock connectors for connecting the solar panel array to a support structure, according to an exemplary embodiment.

FIG. 10 is another end view of a modular solar panel system having adjacent solar panels connected into a solar panel array with peripheral frame members and twist-lock connectors for connecting the solar panel array to a support structure, with the connectors in various stages of activation (or deployment), according to an exemplary embodiment.

FIGS. 11A-11D are perspective views of a quick-release twist-lock connector in various stages of activation (or deployment), according to an exemplary embodiment.

### DETAILED DESCRIPTION

Before turning to the Figures, which illustrate the exemplary embodiments in detail, it should be understood that the application is not limited to the details or methodology set forth in the description or illustrated in the figures. It should also be understood that the terminology is for the purpose of description only and should not be regarded as limiting.

Referring to the FIGURES, a system is provided according to an exemplary embodiment for interconnecting photovoltaic (PV) solar panels to one another and for mounting the connected solar panels to a support structure using quick-connect devices, so that a modular solar panel assembly can be quickly and conveniently assembled to provide a portable source of power (e.g. for base camps, remote outposts, expeditioning, camping, outdoor recreation, work or business activities, etc.) and can be easily disassembled to facilitate transport of the system to other locations.

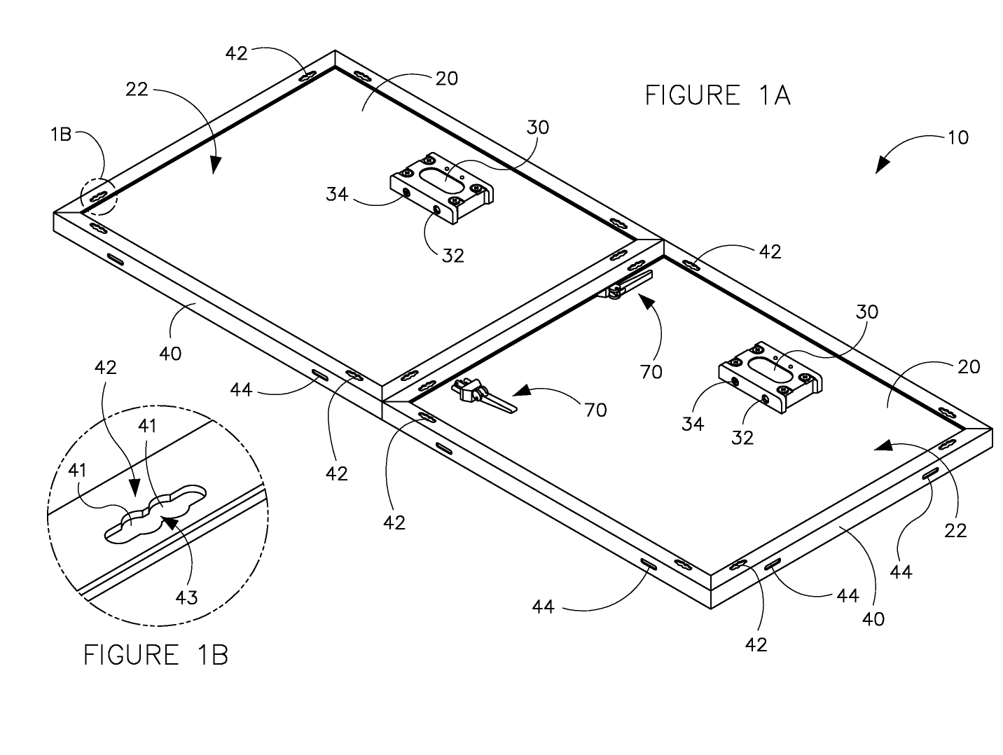

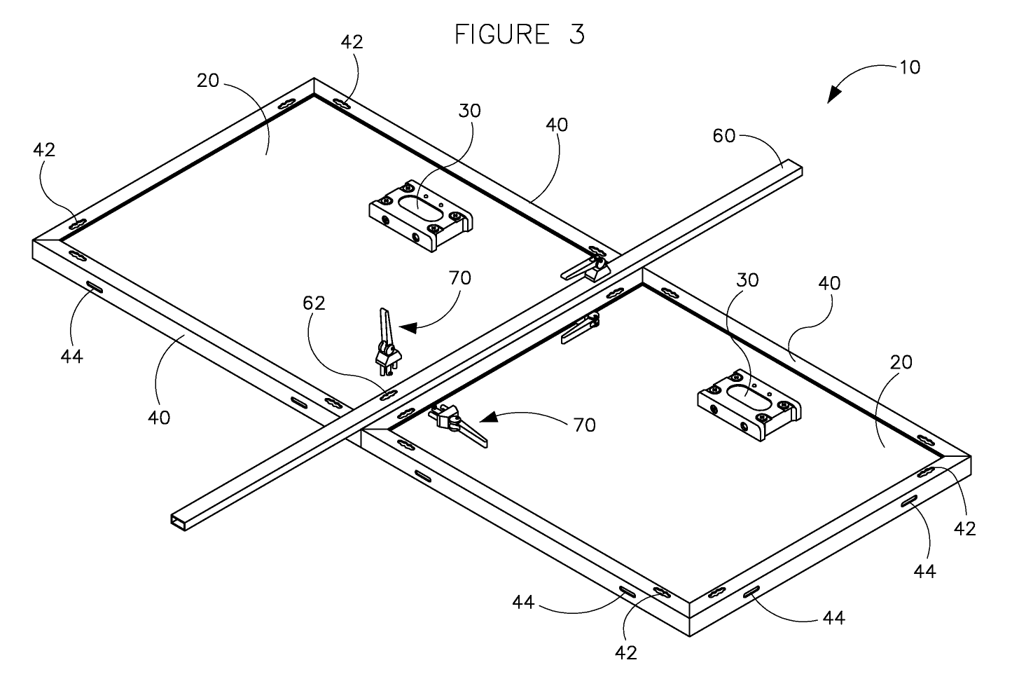

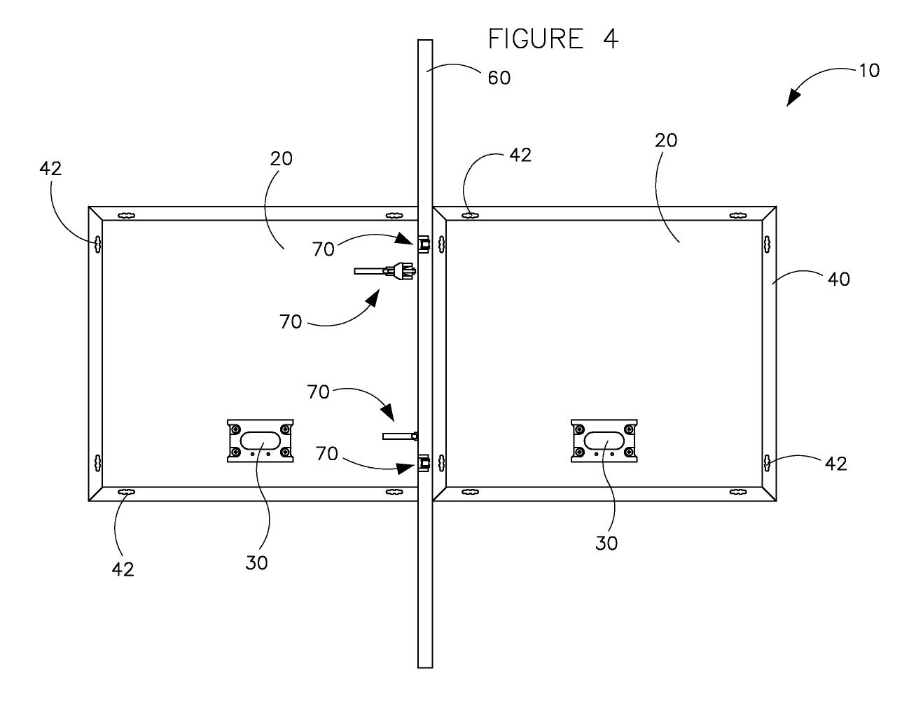

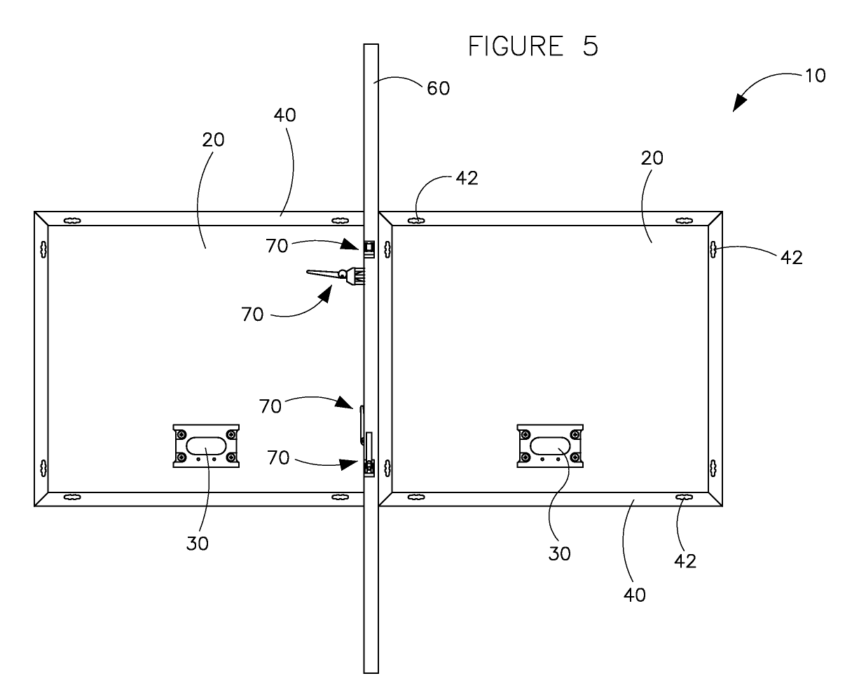

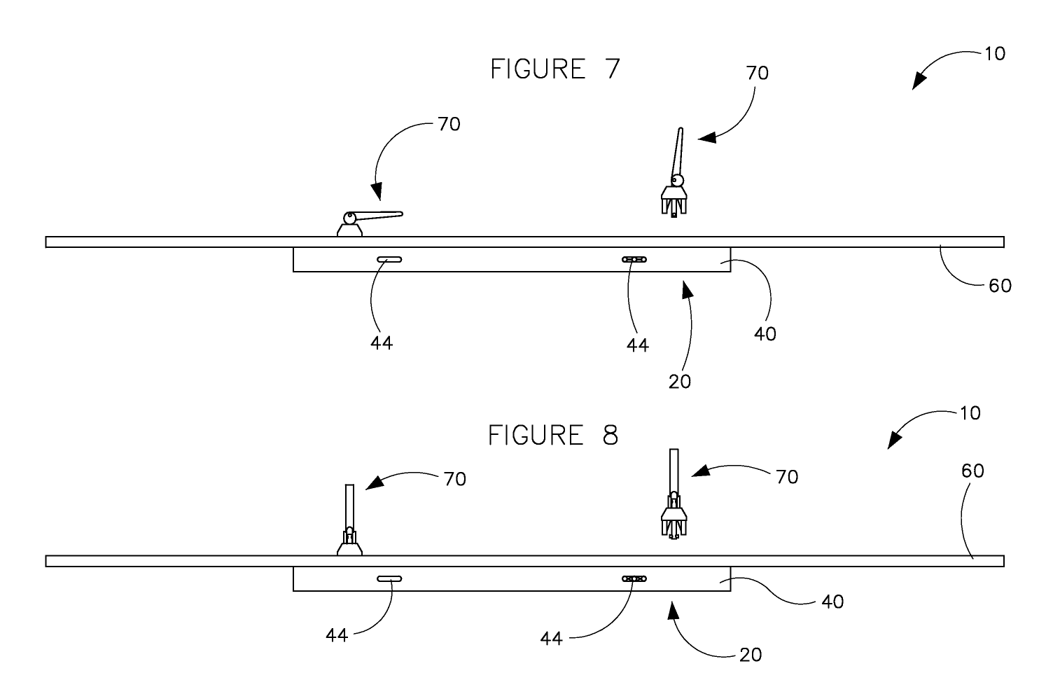

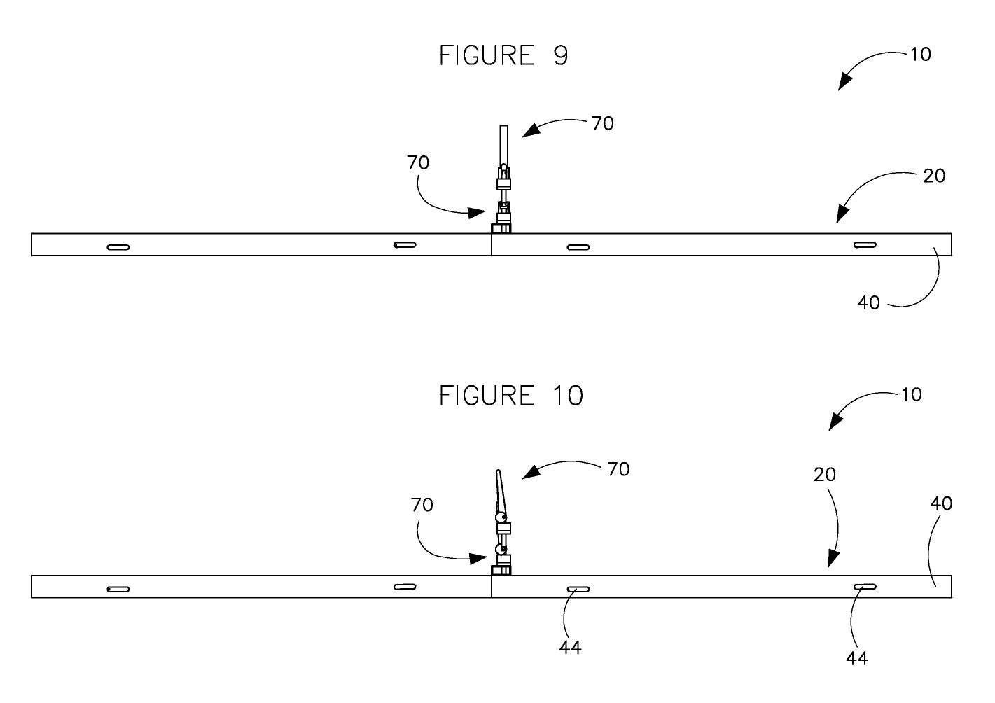

Referring to FIGS. 1-10, a modular solar panel system 10 is provided that includes a plurality of PV solar panels 20 (shown for example as substantially square panels, but may be other shapes) that are mechanically and electrically interconnectable to create a modular solar panel array (e.g. in a building-block manner or the like) having any desired number of solar panels 20 intended to suit the electric power requirements of a particular application and any of a wide variety of loads (i.e. electrical devices, lighting, appliances, tools, portable medical equipment, communication devices, etc.). Each panel 20 includes an electrical connection module 30 having an input connection 32 and an output connection 34 for electrically interconnecting the panels 20 in the solar panel array. The input and output connections 32, 34 may include quick-connect features (e.g. spring-biased contacts, etc.) that facilitate quick and convenient connection of electrical connection wires 36 (e.g. leads, cables, jumpers, etc.). According to one embodiment, the input and output connections 32, 34 may include mutually exclusive or otherwise dissimilar connection devices that engage similarly configured ends of the jumpers so that the panels may be electrically connected in only the correct electrical orientation. The electrical connection modules 30 permits chaining the panels together (e.g. in a ‘plug-and-play’ manner or the like) that permits only one-way, correct-orientation connection of the panels to one another, and preferably have no exposed electrically conductive surfaces, in order to minimize the risk of shocks or shorts due to unintended contact.

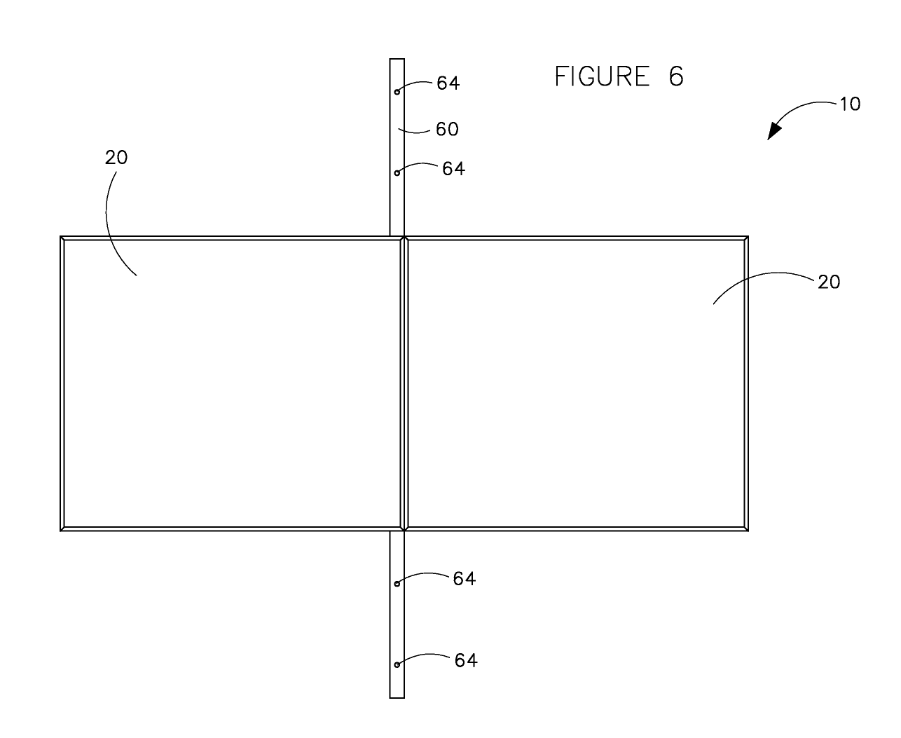

Referring further to the FIGURES, each panel 20 also includes a peripheral frame member 40, extending substantially around the perimeter of the solar panel 20 and providing structural support to the panel 20 for interconnecting adjacent panels 20 and for mounting the panels 20 on a support structure 60. The peripheral frame member 40 for each panel includes a first set of receptacles 42 shown to be arranged on a back face 22 of the solar panel 20. The first set of receptacles 42 are shown in the shape of an elongated linear slot with arcuate (e.g. rounded) ends and two intermediate extensions (e.g. openings, bulges—shown for example as circular openings 41) separated by a middle planar slot segment 43, somewhat in the manner of a “double-keyhole” or the like. The first set of receptacles 42 are intended to be engageable with multiple types of connectors for mounting the solar panel array upon a support structure 60. According to one embodiment, the support structure 60 includes a set of projections 64 (see FIG. 6) having a short “stem” and a flat “head” (e.g. in the manner of a screw head or nail head or the like, that is receivable through the circular opening in the first set of receptacles 42 so that the panel 20 can be shifted laterally to capture the flat head beneath the end of the slot portion (in a slide-lock manner). The use of a double opening in the first set of receptacles is intended to permit the panels to be mounted in any planar orientation relative to the support structure (e.g. upside down, right side up, sideways), etc. The first set of receptacles 42 is also intended to be used with a second type of connection device, shown and described by way of example as a twist-lock device 70 herein, for releasably mounting the array of solar panels 20 on the support structure 60.

Referring further to FIGS. 1-3 and 7-10, each peripheral frame member 40 is also shown to include a second set of receptacles 44 shown to be arranged along an outside edge of the solar panel 20. The second set of receptacles 44 are in the form of linear slots 45 with arcuate (e.g. rounded) ends that are arranged along each of the four (4) sides of the panel 20 so that the receptacles 44 on one panel 20 align with the receptacles 44 on another panel 20 when placed adjacent one another in a generally planar edge-to-edge manner, in any of the four possible planar orientations, to facilitate mechanically connecting the panels 20 using a connection device (shown as a twist-lock connector 70 and further described herein) configured to engage the aligned second set of receptacles 44 on the outside edges of the adjacent solar panels 20.

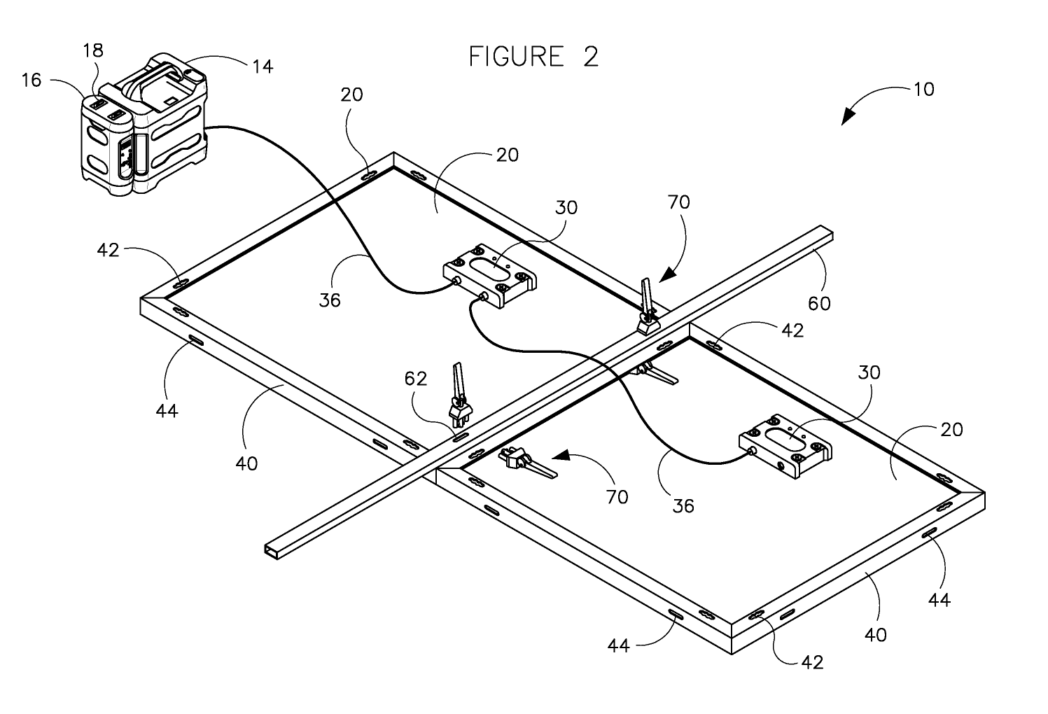

Referring further to FIGS. 2-10, a support structure 60 is provided for receiving (e.g. supporting, securing, etc.) the array of solar panels 20, or for otherwise mounting the solar panel array thereto, according to an exemplary embodiment. The support structure 60 may be a modular structure (e.g. a space frame or the like) configured to be quickly constructed or assembled in a size intended to adapt to the size and support requirements of the solar panel array. The support structure 60 may also be a stand, rack or other type of frame member that is fixed, or collapsible, and is readily transportable from one location where an off-grid source of electric power is desired to another location. The support structure 60 may also be a rack or other framework on a vehicle (e.g. car, truck, bus, recreational vehicle (RV), etc.). The support structure 60 is shown to includes a third set of receptacles 62 that have a size, shape and spacing that corresponds substantially to the size, shape and spacing of the first set of receptacles 42 on the back face 22 of the panel frame member 40 and are alignable with one another to facilitate mounting of the solar panels 20 to the support structure 60 using a connection device 70 configured to engage the aligned receptacles on the support structure and solar panels. Alternatively, the support structure 60 may include projections sized, shaped, and spaced to align with the first set of receptacles 42 on the back face 22 of the solar panel frame 40 so that they releasably engage one another in a secure manner (e.g. slide-lock, etc.).

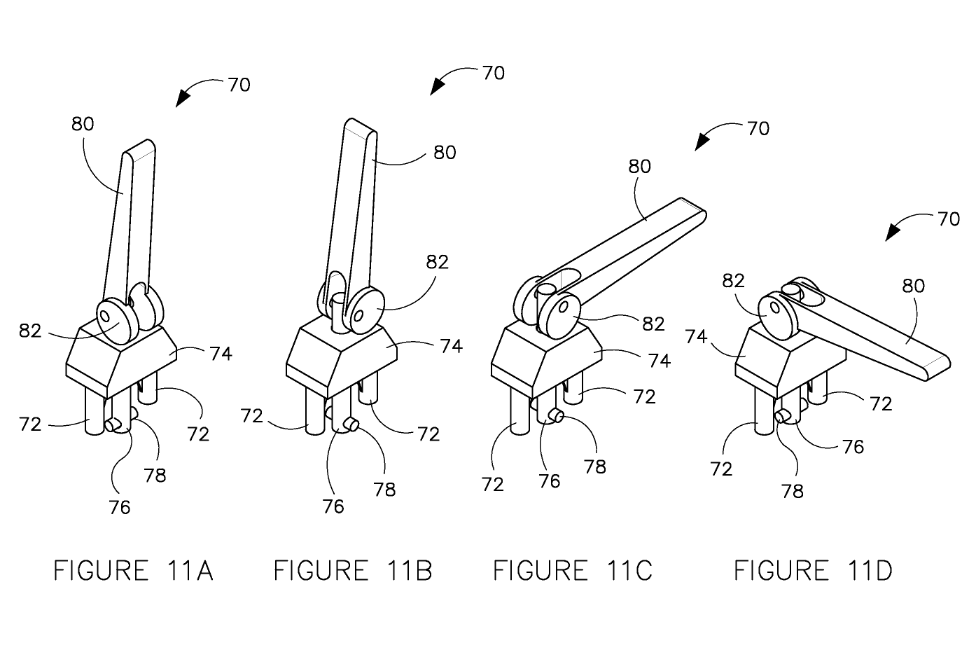

Referring to FIGS. 11A-11D, a quick-release connection device 70 is provided for interconnecting the solar panels 20 to one another and to the support structure 40, according to an exemplary embodiment. The quick release connection device 70 is shown by way of example as a “twist-lock” connector, which has two lateral stationary round posts 72 that are secured to a base portion 74. The connector universally engages the receptacles 42 and 44 in the following manner. For receptacles 42 (on the back face 22 of the panel frame 40), the lateral posts 72 are spaced and sized to engage the two intermediate openings 41, and for receptacles 44, the spacing of the lateral posts 72 corresponds to the length of the linear slot in receptacles 44 and the curvature of the lateral posts substantially corresponds to the curvature of the ends of the slot, so that the posts fit snugly within lots of the aligned receptacles to secure adjacent panels, or a panel and a support structure, in two dimensions along the plane of the solar panels (i.e. along an X axis direction and along a Y axis direction). Connector 70 also includes a rotatable (e.g. quarter-turn) center round post 76 have a projection 78 extending therefrom (e.g. a “T” post) extends through the base portion 74 and is pivotally coupled to a locking lever 80. The locking lever 80 is rotatable through at least a quarter-turn range (e.g. 90 degrees) so that the projection 78 on the T post 76 is movable between a first position for insertion of the stationary posts 72 and center post 76 into the aligned receptacles of two adjacent solar panels 20 or the aligned receptacles of a solar panel 20 and a support structure 60. The lever 80 may then be rotated a quarter-turn to deploy the projection 78 within the middle linear slot segments 43 and 45 of the receptacles 42 and 44 respectively to secure the assembly in a Z axis direction (i.e. perpendicular to the plane of the panels and along the axis of the center post). The lever 80 is pivotally coupled to a top portion of the center post 76 and includes an offset cam portion 82 that engages the top of the base portion 74 as the handle 80 is moved 90 degrees into a locked position (i.e. parallel to the plane of the panels 20). The offset nature of the cam 82 provides an over-center closure that helps to retain the lever 80 in the locked position. According to any preferred embodiment, the twist-lock connectors 70 are configured to releasably engage (i) the aligned sets of receptacles 44 on adjacent outside edges of the solar panel frame members 40 for connecting the panels 20 into a solar panel array, and (ii) receptacles 42 the back face 22 of the solar panel frame members 40 and the support structure 60 to mount the solar panel array on the support structure.

According to any exemplary embodiment of the present invention, one or more battery modules 14 may be electrically coupled to the electrical connection modules 30 of the solar panels 20 to store electrical energy generated by the solar panels 20. An inverter module 16 may be provided that is connectible to the battery module 14 and includes a ‘multi-standard’ socket 18 configured to receive any of a wide variety of electric plug configurations to provide a source of AC electric power. One example of a battery module and inverter module are shown in U.S. Patent Application No. 61/308,712 titled “Modular and Portable Battery Pack Power System” filed on Feb. 26, 2010, the disclosure of which is hereby incorporated by reference in its entirety. Another example of a battery module and inverter module are shown in U.S. Patent Application No. 61/347,735 titled “Modular and Portable Battery Pack Power System” filed on May 28, 2010, the disclosure of which is hereby incorporated by reference in its entirety.

It is also important to note that the construction and arrangement of the elements of the modular solar panel system as shown schematically in the embodiments is illustrative only. Although only a few embodiments have been described in detail in this disclosure, those skilled in the art who review this disclosure will readily appreciate that many modifications are possible without materially departing from the novel teachings and advantages of the subject matter recited. For example, although the connection system has been shown by way of example as used for modularly interconnecting and mounting solar panels, the connection system may be used to connect other devices to one another for use in providing (or facilitating) a portable source of off-grid power, such as wind power devices, hydropower devices, etc.

Accordingly, all such modifications are intended to be included within the scope of the present invention. Other substitutions, modifications, changes and omissions may be made in the design, operating conditions and arrangement of the preferred and other exemplary embodiments without departing from the spirit of the present invention.

Unless otherwise indicated, all numbers used in the specification and claims are to be understood as being modified in all instances by the term “about.” Accordingly, unless indicated to the contrary, the numerical parameters set forth in the following specification and attached claims are approximations that may vary depending at least upon the specific analytical technique, the applicable embodiment, or other variation according to the particular configuration of the modular solar panel system.

The order or sequence of any process or method steps may be varied or re-sequenced according to alternative embodiments. In the claims, any means-plus-function clause is intended to cover the structures described herein as performing the recited function and not only structural equivalents but also equivalent structures. Other substitutions, modifications, changes and omissions may be made in the design, operating configuration and arrangement of the preferred and other exemplary embodiments without departing from the spirit of the present invention as expressed in the appended claims.

What is claimed is:

1. A modular solar panel system, comprising:
a plurality of solar panels that are mechanically and electrically interconnectable to create a modular solar panel array;
an electrical connection module on each panel, the module having an input connection and an output connection for electrically interconnecting the panels in the solar panel array;
a peripheral frame member disposed about each panel, the peripheral frame member including a first set of receptacles arranged on a back face, and a second set of receptacles arranged along an outside edge, wherein the second set of receptacles are arranged along each side so that the receptacles on one panel align with the receptacles on another panel when placed adjacent one another in a generally planar edge-to-edge manner;
a support structure configured to support the solar panel array, the support structure including a third set of receptacles that have a size, shape and spacing that correspond substantially to the size, shape and spacing of the first set of receptacles on the back face and are alignable with one another to facilitate mounting of the solar panels to the support structure; and
connection devices for interconnecting the solar panels to one another and to the support structure.

2. The modular solar panel system of claim 1 wherein the electrical connection modules permit electrically chaining the panels together and permits only one-way, correct-orientation connection of the panels to one another, and have no exposed electrically conductive surfaces.

3. The modular solar panel system of claim 1 wherein the support structure comprises at least one a space frame, a stand and a rack.

4. The modular solar panel system of claim 3 wherein the support structure comprises projections that are sized, shaped, and spaced to align with the first set of receptacles on the back face so that they releasably engage one another in a slide-lock manner.

5. The modular solar panel system of claim 1 wherein the connection devices comprise twist-lock connectors with two lateral stationary posts and a rotatable center “T” post that is pivotally coupled to a locking lever having an over-center cam.

6. The modular solar panel system of claim 5 wherein the twist-lock connectors are configured to releasably engage aligned sets of receptacles on adjacent outside edges of the solar panel frame members for connecting the panels into the solar panel array, and the back face of the solar panel frame members and the support structure to mount the solar panel array on the support structure.

7. The modular solar panel system of claim 1 further comprising one or more battery modules electrically coupled to the electrical connection modules of the solar panels to store electrical energy generated by the solar panels.

8. The modular solar panel system of claim 7 further comprising an inverter module connected to the battery module.

9. The modular solar panel system of claim 8 wherein the inverter module includes a multi-standard socket configured to receive any of a wide variety of electric plug configurations to provide a source of AC electric power.

10. The modular solar panel system of claim 8 wherein the inverter module is configured for use with AC loads and DC loads.

11. The modular solar panel system of claim 1 wherein the first set of receptacles comprise an elongated linear slot with rounded ends and two intermediate circular openings separated by a middle planar slot segment.

12. The modular solar panel system of claim 1 wherein the support structure includes a set of projections having a short stem and a flat head that is receivable through the circular opening in the first set of receptacles so that the panel can be shifted laterally to capture the flat head beneath the end of the slot portion in a slide-lock manner.

13. A modular solar panel system, comprising:
a plurality of solar panels that are mechanically and electrically interconnectable to create a modular solar panel array;
an electrical connection module coupled to each panel, the modules having an input connection and an output connection for electrically interconnecting the panels in the solar panel array;
a frame member disposed about each panel, the frame member including a first set of receptacles arranged on a back face, and a second set of receptacles arranged along an outside edge, so that the second set of receptacles on one panel align with the second set of receptacles on another panel when placed adjacent one another in a generally planar edge-to-edge manner;
a support structure configured to support the solar panel array, the support structure including a third set of receptacles that have a size, shape and spacing that correspond substantially to the size, shape and spacing of the first set of receptacles on the back face and are alignable with one another to facilitate mounting of the solar panels to the support structure;
a plurality of twist-lock connection devices for interconnecting the solar panels to one another and to the support structure;
a battery module electrically connectible to the electrical connection modules; and
an inverter module electrically connectible to the battery module.

14. The modular solar panel system of claim 13 wherein the twist-lock connectors comprise two lateral stationary posts and a rotatable center “T” post that is pivotally coupled to a locking lever having an over-center cam.

15. The modular solar panel system of claim 14 wherein the twist-lock connectors are configured to releasably engage aligned sets of receptacles on adjacent outside edges of the solar panel frame members for connecting the panels into the solar panel array, and the back face of the solar panel frame members and the support structure to mount the solar panel array on the support structure.

16. A modular solar panel system, comprising:
a plurality of solar panels that are interconnectable to create a solar panel array;
each panel having an electrical connection module with an input connection and an output connection for electrically interconnecting the panels in the solar panel array;
each panel also having a frame member with first receptacles on a back face, and second receptacles on an outside edge, so that the second receptacles on one panel align with the second receptacles on another panel when placed adjacent one another in a generally planar edge-to-edge manner;
a support structure configured to support the solar panel array, the support structure including third receptacles corresponding substantially with the first receptacles on the back face and are alignable with one another to facilitate mounting of the solar panels to the support structure;
a plurality of quick-release connection devices that are universally engageable with the first receptacles, and the second receptacles, and the third receptacles for interconnecting the solar panels to one another and to the support structure;
a battery module electrically connectible to the electrical connection modules; and
an inverter module electrically connectible to the battery module.
